(19) United States
(12) Patent Application Publication
(10) Pub. No.: US 2012/0251824 A1
(43) Pub. Date: Oct. 4, 2012

(54) Stretchable Conductive Nanofibers, Stretchable Fiber Electrode Using The Same And Method For Producing The Same

(75) Inventors: Jae-hyun Hur, Yongin-si (KR); Jong-jin Park, Hwaseong-si (KR); Kyu-hyun Im, Yongin-si (KR); Un-yong Jeong, Seoul (KR); Min-woo Park, Seoul (KR)

(73) Assignees: Industry-Academic Cooperation Foundation, Yonsei University, Seoul (KR); SAMSUNG ELECTRONICS CO., LTD., Suwon-si (KR)

(21) Appl. No.: 13/297,308

(22) Filed: Nov. 16, 2011

(30) Foreign Application Priority Data
Apr. 1, 2011 (KR) 10-2011-0030287

(51) Int. Cl. B32B 9/00; B05D 5/12; C23C 14/28; B82Y 40/00

(52) U.S. Cl. 428/378; 427/595; 427/113; 977/847

(57) ABSTRACT

Example embodiments relate to stretchable conductive nanofibers including at least one stretchable nanofiber and a conductive layer on a structure of the stretchable nanofiber. The conductive layer may include carbon nanotubes and metal nanoparticles on the surface of the stretchable nanofiber. The carbon nanotubes and metal nanoparticles may form a percolation network. The stretchable nanofiber includes stretchable polymers.

### CROSS-REFERENCE TO RELATED APPLICATIONS

This application claims priority under 35 U.S.C. §119 to the benefit of Korean Patent Application No. 10-2011-0030287, filed on Apr. 1, 2011, in the Korean Intellectual Property Office, the contents of which are incorporated herein in its entirety by reference.

### BACKGROUND

1. Field

Example embodiments relate to a stretchable conductive fiber, a method for producing the same, and more particularly, to a stretchable fiber electrode and a method for producing the same.

2. Description of the Related Art

Fiber-based electronic devices are still a theoretical concept, but they may replace some electronic devices in the marketplace. Fibers may include desirable tensile and weaving properties, large surface areas, various surface treatments, and may be formed into composites. Examples of fiber-based electronic devices are textile solar cells, stretchable transistors, stretchable displays, exterior-stimulated drug delivery, biosensors and gas sensors, light-controlling functional textiles, functional clothing, functional products for the defense industry, etc.

In the field of micro-electronic devices, devices having flexibility and stretchability are desirable. It is desirable to develop electrodes that are stretchable and maintain conductivity. Materials such as metals may have good conductivity, but they may be rigid and stiff. When materials such as carbon nanotubes or graphenes are used on their own, it is also difficult to make stretchable electrodes.

As examples of methods for making stretchable electrodes, the following methods have been disclosed: the production of a paste by mixing carbon nanotubes, transparent fluoro-polymers and ionic liquids; the production of a pattern using a paste of metal particles and polyacrylic acids by an inkjet method; the formation of a metal layer on a pleated PDMS substrate to cause stretchability by unfolding pleats; etc. However, in these methods, the stretchability is low, resulting in exhibiting the dramatic lowering of conductivity and/or mechanical breakage during a stretching process.

### SUMMARY

Example embodiments relate to stretchable conductive nanofibers.

Example embodiments relate to methods for producing stretchable conductive nanofibers.

According to example embodiments, a stretchable conductive nanofiber includes at least one stretchable nanofiber, and a conductive layer including carbon nanotubes and metal nanoparticles on the surface of the stretchable nanofiber.

The carbon nanotubes and metal nanoparticles may form a percolation network.

The stretchable nanofiber may include stretchable polymers.

The stretchable polymers may include one of polybutadiene (PB), poly(styrene-butadiene) (PS-b-PB, PS-co-PB), poly(styrene-butadiene-styrene) (PS-b-PB-b-PS) (SBS), poly(styrene-ethylene-butylene-styrene) (SEBS), polyurethane (PU), polyisoprene, and combinations thereof.

The stretchable nanofiber may include at least one of carbon nanotubes and metal nanoparticles inside the nanofiber.

The carbon nanotubes may include at least one of single-wall carbon nanotubes (SWNTs) and multi-wall carbon nanotubes (MWNTs).

The carbon nanotubes may include an aspect ratio of 100˜5000.

The metal nanoparticles may include at least one of silver, gold, copper, platinum, and combinations thereof.

The stretchable nanofiber may include at least one of carbon nanotubes and metal nanoparticles inside the stretchable nanofiber.

According to example embodiments, a mat may include at least one stretchable conductive nanofiber.

According to example embodiments, a method for producing stretchable conductive nanofibers includes (a) depositing carbon nanotubes on stretchable nanofibers by immersing stretchable nanofibers in a solution of carbon nanotubes, removing the stretchable nanofibers from the solution, and drying the stretchable nanofibers; (b) subjecting the stretchable nanofibers including carbon nanotubes deposited thereon to a UV-ozone treatment; (c) additionally depositing carbon nanotubes on the stretchable nanofibers including carbon nanotubes deposited thereon by immersing the stretchable nanofibers including carbon nanotubes deposited thereon in the solution of carbon nanotubes, removing the stretchable nanofibers including carbon nanotubes deposited thereon, and drying the stretchable nanofibers including carbon nanotubes deposited thereon; and (d) repeating several times the operations (b) and (c) sequentially to form a conductive layer including carbon nanotubes on the stretchable nanofibers.

The stretchable nanofibers may include stretchable polymers.

The stretchable nanofibers may be in the form of a mat.

According to example embodiments, a method for producing stretchable conductive nanofibers includes (a) depositing metal precursors on stretchable nanofibers by immersing stretchable nanofibers in a solution of metal precursors, removing the stretchable nanofibers from the solution, and drying the stretchable nanofibers; (b) reducing the metal precursors deposited on the stretchable nanofibers to metals using a reducing agent; and (c) repeating several times the operations (a) and (b) to form a conductive layer including metal nanoparticles on the stretchable nanofibers.

The stretchable nanofibers may include stretchable polymers.

The stretchable nanofibers may be in the form of a mat.

The metal precursors may include one of AgNO3, AgCF3COOH, HAuCl4, CuCl2, PtCl2, PtCl4, and combinations thereof.

The reducing agent may include one of hydrazine (N2H4) and Sodium borohydride (NaBH4).

According to example embodiments, a method for producing stretchable conductive nanofibers includes (a) depositing carbon nanotubes on stretchable nanofibers by immersing stretchable nanofibers in a solution of carbon nanotubes, removing the stretchable nanofibers from the solution of carbon nanotubes, drying the stretchable nanofibers; (b) depositing metal precursors on the stretchable nanofibers including carbon nanotubes deposited thereon by immersing the stretchable nanofibers including carbon nanotubes deposited thereon in a solution of metal precursors, removing the stretchable nanofibers including carbon nanotubes deposited thereon from the solution of metal precursors, drying the stretchable nanofibers including carbon nanotubes deposited thereon, and reducing the metal precursors deposited on the stretchable nanofibers to metals using a reducing agent; and (c) repeating several times the operations (a) and (b) to form a conductive layer including metal nanoparticles on each of the stretchable nanofibers.

Stretchable conductive nanofibers according to example embodiments may maintain (or substantially maintain) conductivity during a tensile process by forming a percolation network of carbon nanotubes and/or metal nanoparticles on stretchable nanofibers.

According to example embodiments, carbon nanotubes and/or metal nanoparticles may be densely formed on stretchable nanofibers, resulting in a percolation network including carbon nanotubes and/or metal nanoparticles.

### BRIEF DESCRIPTION OF THE DRAWINGS

These and/or other features of example embodiments will become apparent and more readily appreciated from the following description of the non-limiting embodiments, as illustrated in the accompanying drawings, in which like reference characters refer to the same parts throughout the different views. The drawings are not necessarily to scale, emphasis instead being placed upon illustrated the principles of the inventive concepts. In the drawings:

FIG. 1 is a view showing stretchable conductive nanofibers, according to example embodiments.

FIG. 2 is a view showing stretchable conductive nanofibers according to example embodiments.

FIGS. 3A and 3B are views showing stretchable conductive nanofibers according to example embodiments.

FIG. 4 is a flowchart illustrating a method for producing stretchable conductive nanofibers, according to example embodiments.

FIG. 5 is a view showing a process for forming stretchable conductive nanofibers by repeating a carbon nanotubes-depositing process, according to example embodiments.

FIG. 6 is a flowchart illustrating a method for producing stretchable conductive nanofibers, according to example embodiments.

FIG. 7 is a view showing forming metal nanoparticles on stretchable nanofibers by the reduction of metal precursors, according to example embodiments.

FIG. 8 is a flowchart illustrating a method for producing stretchable conductive nanofibers, according to example embodiments.

FIG. 9 is a view showing a process for forming stretchable conductive nanofibers by the deposition of carbon nanotubes and metal nanoparticles.

FIG. 10 are photographs showing the extent of stretching a SBS nanofiber mat formed by electro-spinning in the intermediate stage of Example 5.

FIG. 11 is a graph showing current-voltage properties of carbon nanotubes-deposited SBS nanofibers as the function of carbon nanotube depositions.

FIG. 12 is a graph showing electrical conductivities of carbon nanotubes-deposited SBS nanofibers as the function of carbon nanotube depositions.

FIG. 13 is a photograph of a silver nanoparticles-deposited SBS nanofiber mat formed in Example 6.

FIG. 14 is a thermogravimetry analysis graph showing weights of a silver nanoparticles-deposited SBS nanofiber mat formed in Example 6 with respect to temperature.

FIG. 15 is a graph showing surface resistance measurements while stretching uniaxially a silver nanoparticles-deposited SBS nanofiber mat formed in Example 6.

FIG. 16 is a graph showing current-to-voltage measurements while stretching uniaxially a carbon nanotubes and silver nanoparticles deposited SBS nanofiber mat formed in Example 7.

FIG. 17 is a view showing an electronic device according to example embodiments.

FIG. 18 is a view showing a sensor according to example embodiments.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey concepts of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

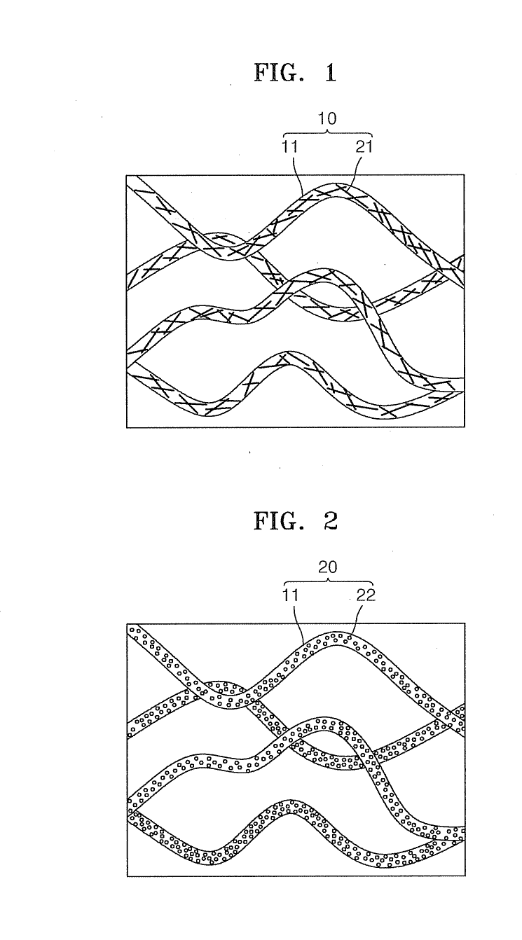

FIG. 1 illustrates a view showing stretchable conductive nanofibers 10 according to example embodiments. With reference to FIG. 1, the stretchable conductive nanofibers 10 include carbon nanotubes 21 which form a percolation network on the surfaces of stretchable nanofibers 11. The percolation network includes a network formed by unit particles and/or elements arranged and connected to each other in any direction.

The stretchable nanofibers 11 may include, for example, polymer materials. Polymers in the stretchable nanofibers 11 may include synthetic rubbers and/or natural rubbers, but example embodiments are not limited thereto. Examples of synthetic rubbers may be polybutadiene (PB), poly(styrene-butadiene) (PS-b-PB, PS-co-PB), poly(styrene-butadiene-styrene) (PS-b-PB-b-PS) (SBS), poly(styrene-ethylene-butylene-styrene) (SEBS), or polyurethane (PU). Examples of natural rubbers include polyisoprene, but example embodiments are not limited thereto.

The carbon nanotubes 21 may be single-wall carbon nanotubes (SWNTs) or multi-wall carbon nanotubes (MWNTs), and combinations thereof.

The stretchable nanofibers 11 may have a diameter in the range of 0.1˜5.0 μm. The carbon nanotubes 21, which form a percolation network on the stretchable nanofibers 11, may have a diameter in the range of 1˜2 nm and a length in the range of 0.2˜5.0 μm. The carbon nanotubes 21 may have an aspect ratio of about 100˜5000. The carbon nanotubes 21 may have a range of 1˜20 parts by weight based on total 100 parts by weight of the stretchable conductive nanofibers 10. The layer of the carbon nanotubes 21 on the stretchable nanofibers 11 may have a thickness in the range of 0.01˜0.1 μm.

When the stretchable nanofibers 11 are stretched, the layer of the carbon nanotubes 21 thereon is generally not broken or cut because the nanofibers 11 resist the tensile stress from stretching and the carbon nanotubes 21 form a percolation network and thus only the distance between the carbon nanotubes 21 becomes longer temporarily. Additionally, the conductivity of the layer may be maintained (or substantially maintained) because electrical paths may be maintained by a percolation network including carbon nanotubes.

FIG. 2 is a view showing stretchable conductive nanofibers 20 according to example embodiments. With reference to FIG. 2, the stretchable conductive nanofibers 20 include metal nanoparticles 22 which form a percolation network on the surfaces of the stretchable nanofibers 10.

The stretchable nanofibers 11 illustrated in FIG. 2 are the same as (or substantially the same as) the nanofibers 11 of FIG. 1 so a repetitive description is omitted.

The metal nanoparticles 22 may include, for example, silver, gold, copper, platinum, and combinations thereof. The layer of the metal nanoparticles 22 may account for about 40˜80 parts by weight based on total 100 parts by weight of the stretchable conductive nanofibers 20. The metal nanoparticles 22 may have a diameter in the range of 5˜100 nm. The layer of the metal nanoparticles 22 may have a thickness in the range of 5˜500 nm. The metal nanoparticles 22 may have the range of 20˜65 parts by weight based on total 100 parts by weight of the stretchable conductive nanofibers 20.

When the stretchable nanofibers 11 are stretched, the metal nanoparticles 22 thereon are generally not broken or cut, because the nanofibers 11 resist the tensile stress from stretching and the metal nanoparticles 22 form a percolation network and thus only the distance between the metal nanoparticles 22 becomes longer temporarily. Additionally, the conductivity of the metal layer may be maintained (or substantially maintained) because electrical paths may be maintained by a percolation network including the metal nanoparticles 22.

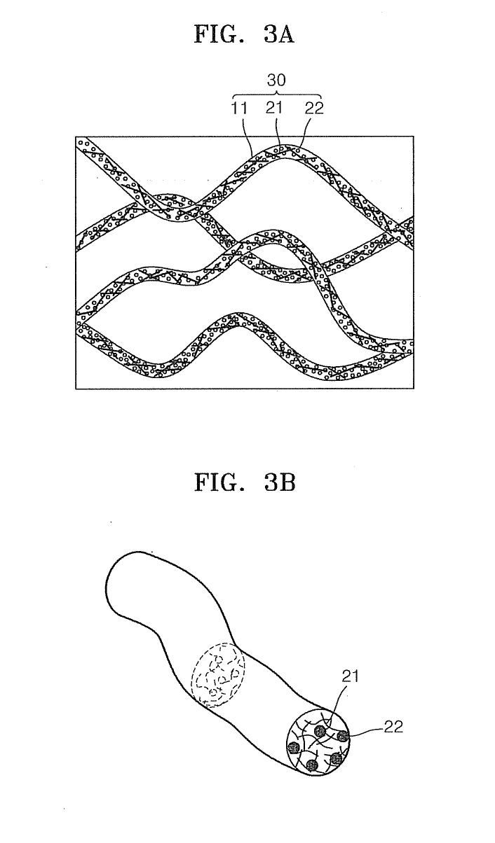

FIGS. 3A and 3B are views showing stretchable conductive nanofibers 30 according to example embodiments. With reference to FIGS. 3A and 3B, the stretchable conductive nanofibers 30 include carbon nanotubes 21 and metal nanoparticles 22 which form a percolation network together on the surfaces of the stretchable nanofibers 11. As shown in FIGS. 3A and 3B, the stretchable nanofibers 11 and the carbon nanotubes 21 are the same as (or substantially the same as) the nanofibers 11 and the carbon nanotubes 21 illustrated in FIG. 1, and the metal nanoparticles 22 are the same as (or substantially the same as) the metal nanoparticles 22 illustrated in FIG. 2 so repetitive description is omitted.

A high electrical conductivity may be obtained by the metal nanoparticles 22, and more electrical paths may be retained by the connection of the carbon nanotubes 21 to the metal nanoparticles 22 during the stretching of the stretchable nanofibers 11, thereby obtaining good conductivity and stretchability.

According to example embodiments, a mat may be formed using stretchable conductive nanofibers 10, 20 and/or 30. The mat may be used as a stretchable electrode, but example embodiments are not limited thereto.

Moreover, as illustrated in FIGS. 3A and 3B, the stretchable nanofibers 11 of the stretchable conductive nanofibers 10, 20 and 30 may include carbon nanotubes and/or metal nanoparticles inside the nanofibers. In example embodiments, the carbon nanotubes and/or metal nanoparticles in the stretchable conductive nanofibers may be the same as or different than the carbon nanotubes 21 and/or metal nanoparticles 22 on the stretchable nanofibers 11.

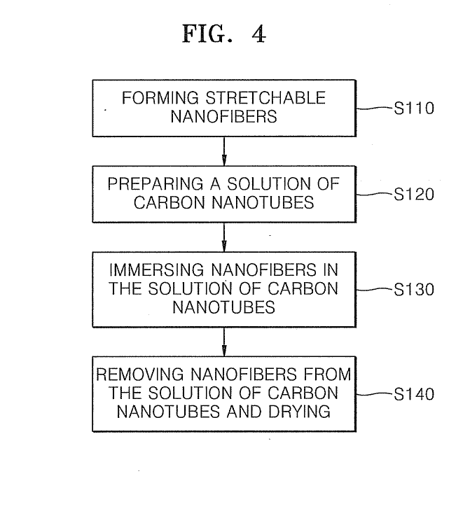

FIG. 4 is a flowchart illustrating a method for producing stretchable conductive nanofibers, according to example embodiments.

Referring to FIG. 4, first, stretchable nanofibers are formed (S110). The stretchable nanofibers may be formed by an electro-spinning method using stretchable polymer materials, but example embodiments are not limited thereto. Alternatively, other methods than electro-spinning, such as wet spinning, conjugated spinning, melt-blown spinning or flash spinning may be used. The resulting stretchable nanofibers may have a diameter of 500 nm to 100 μm.

To form the stretchable nanofibers by the electro-spinning method, first, a polymer solution including a constant (or substantially) viscosity is forced into a nozzle by a pump, for example a cylinder pump, at a constant (or substantially constant) rate. A voltage above a few kV is applied to the tip of the nozzle having a droplet of the polymer solution, and the droplet is distorted to form a Taylor cone. The polymer solution is jetted when an electrostatic repulsion generated by the surface charge of the Taylor cone is greater than its surface tension. At the same time, solvents are evaporated and polymer nanofibers may be obtained along an electrical field formed between the nozzle and a grounded collector. Moreover, a mat of the stretchable conductive nanofibers may be formed by depositing the polymer nanofibers on the collector.

The morphology and diameter of stretchable nanofibers may vary depending on factors such as the molecular weight of the polymer, the type of solvent, an applied voltage, the spinning distance, the spinning temperature, the spinning humidity, etc. Mechanical, electrical and optical properties of nanofibers may vary depending on intrinsic properties and/or chemical structures of base materials.

As polymers capable of forming stretchable nanofibers, synthetic rubbers such as polybutadiene (PB), poly(styrene-butadiene) (PS-b-PB, PS-co-PB), poly(styrene-butadiene-styrene) (PS-b-PB-b-PS) (SBS), poly(styrene-ethylene-butylene-styrene) (SEBS), or polyurethane (PU), and natural rubbers such as polyisoprene may be used, but example embodiments are not limited thereto.

Since the above-mentioned synthetic and/or natural rubbers processed by the electro-spinning method have not been cured, the resulting nanofibers may have higher stretchability as compared to cured polymers such as poly(dimethylsiloxane) (PDMS).

Chloroform, chlorobenzene, toluene, dimethylformaldehyde, tetrahydrofuran, dimethyl sulfoxide, N-methylpyrrolidone or FLUORINERT™ (a family of perfluorinated liquids sold commercially by 3M Company, including perfluorohexane and perfluoro(2-butyl-tetrahydrofurane)) may be used as solvents to dissolve the above-mentioned polymers in order to form a polymer solution including a desired (and/or suitable) viscosity.

Stretchable nanofibers including carbon nanotubes and/or metal precursors may be formed by electro-spinning a polymer solution including carbon nanotubes and/or metal precursors, but example embodiments are not limited thereto.

Referring to back FIG. 4, a solution of carbon nanotubes is prepared (S120). Although the conductivity of the carbon nanotubes may vary depending on the surface treatment methods used, carbon nanotubes may have the high conductivity compared to many organic materials. The solution of carbon nanotubes may be prepared by mixing carbon nanotubes with known suitable solvents. For example, an isopropyl alcohol solution in water may be used as a solvent, but example embodiments are not limited thereto. Also, the surface property of carbon nanotubes may be modified by treating carbon nanotubes with ultrasonic waves in an acid mixture, for example a mixture of nitric acid and hydrochloric acid, prior to the preparation of carbon nanotubes solution, thereby preventing the cohesion of carbon nanotubes. The acid treatment renders the surfaces of carbon nanotubes a negative charge, resulting in an electrostatic repulsion and reducing the cohesion of carbon nanotubes. Further, dispersed and refined carbon nanotubes by centrifugation may also be used.

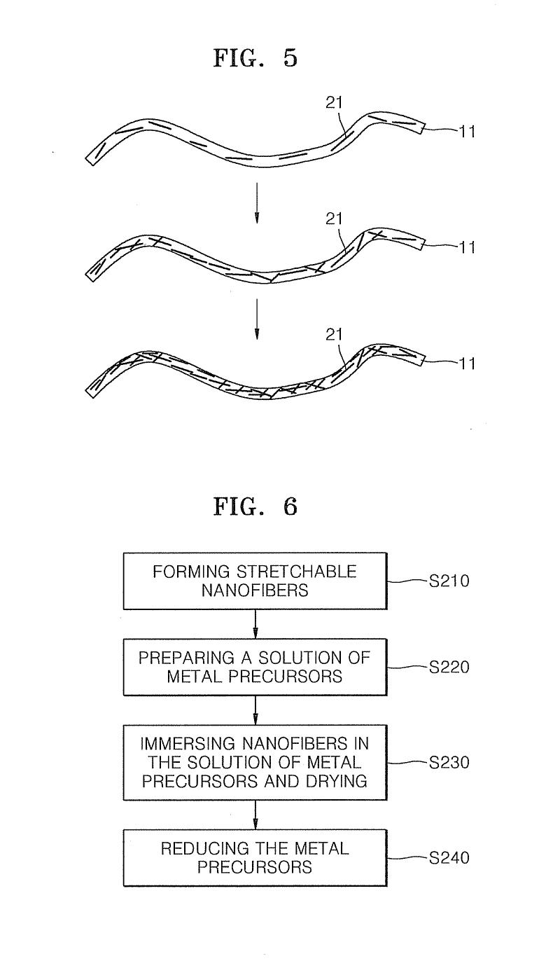

The stretchable nanofibers are immersed in the solution of carbon nanotubes to deposit the carbon nanotubes on the surfaces of the stretchable nanofibers (S130). When a mat is formed using the stretchable nanofibers, the mat of stretchable nanofibers may be immersed in the solution of carbon nanotubes. After a desired (or predetermined) time, the stretchable nanofibers are removed from the solution of carbon nanotubes and dried (S140). Thus, the carbon nanotubes may be deposited on the stretchable nanofibers at a higher density by repeating the immersion and drying of stretchable nanofibers (a dip coating process), thereby improving the electrical conductivity and percolation network of stretchable conductive nanofibers. For example, a single dip coating process in which each of immersion and drying is performed once may be repeated 3˜10 times, and/or more or fewer times. FIG. 5 shows that the network of carbon nanotubes 21 on surfaces of nanofibers 11 becomes more dense as a single dip coating process is repeated. Although not shown in FIG. 5, the dip coating process may be repeated in the same solution of carbon nanotubes or a different solution of carbon nanotubes. In other words, a solution of carbon nanotubes used for the first dip coating process may be the same as or different than a solution used for the second (or third, fourth, etc.) dip coating process.

The stretchable nanofibers may be subjected to a UV-ozone treatment between single dip coating processes. The UV-ozone treatment can lower the surface energy of stretchable nanofibers and carbon nanotubes, which can improvise the adhesion between stretchable nanofibers and carbon nanotubes and/or improve adhesion between carbon nanotubes.

FIG. 6 is a flowchart illustrating a method for producing stretchable conductive nanofibers, according to example embodiments.

With reference to FIG. 6, a process for forming stretchable nanofibers (S210) is the same as previously discussed in FIG. 4 so a repetitive description is omitted.

Next, a solution of metal precursors is prepared (S220). As metal precursors, for example, AgNO₃, AgCF₃COOH, HAuCl₄, CuCl₂, PtCl₂ or PtCl₄ may be used, but example embodiments are not limited thereto. Many solvents may be used as long as the metal precursors are dissolved. For example, silver nitrate (AgNO₃) may be dissolved in ethanol to prepare a solution of silver nitrate in ethanol.

The stretchable nanofibers are immersed in the solution of metal precursors, removed from the solution, and dried to deposit the metal precursors on the surfaces of the stretchable nanofibers (S230). When a mat is formed using the stretchable nanofibers, the mat of stretchable nanofibers may be immersed in the solution of metal precursors.

Washing the stretchable nanofibers with water may be further performed prior to the immersion and drying.

Next, the metal precursors on the stretchable nanofibers are reduced to metals (S240). The reduction of the metal precursors to metals may be performed by treating the metal precursors deposited on the stretchable nanofibers with a reducing agent. For example, the stretchable nanofibers having the metal precursors deposited thereon may be exposed to hydrazine (N₂H₄) vapor or dipped into an ethanol solution, so that the metal precursors on the surfaces of the stretchable nanofibers may be reduced to metal nanoparticles, but example embodiments are not limited thereto and other reducing agents may be suitable. When stretchable nanofibers include metal precursors inside fibers, the metal precursors inside fibers may be reduced to metal nanoparticles simultaneously with the reduction of metal precursors on the surfaces of the stretchable nanofibers. After treating the stretchable nanofibers with a reducing agent, drying washing drying processes may be further performed.

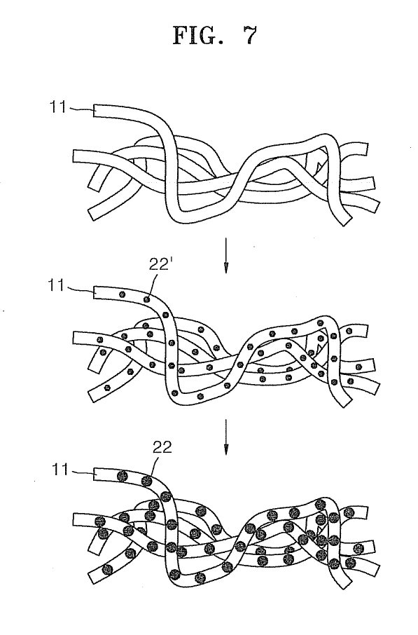

FIG. 7 shows forming metal nanoparticles on stretchable nanofibers by the reduction of the metal precursors. Numerical number 22′ represents metal precursors. Since metal precursors 22′ may be more easily and densely deposited on nanofibers than metal nanoparticles, metal precursors 22′ are deposited on nanofibers, and then the metal precursors 22′ are reduced to metals to form densely and stable metal nanoparticles 22 on nanofibers 11.

Furthermore, the metal nanoparticles 22 may be deposited on stretchable nanofibers 11 at higher densities by repeating the deposition (S230) and reduction (S240). Increasing the density of metal nanoparticles 22 on stretchable nanofibers 11 may improve the electrical conductivity and percolation network of stretchable conductive nanofibers. In addition, the dip coating process may be repeated in the same solution of metal nanoparticles or a different solution of metal nanoparticles. In other words, a solution of metal nanoparticles used for the first dip coating process may be the same as or different than a solution used for the second (or third, fourth, etc.) dip coating process.

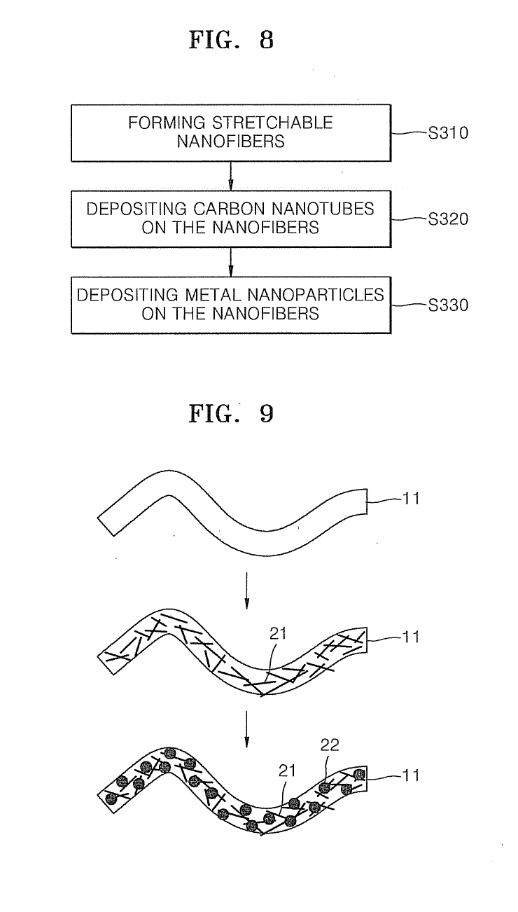

FIG. 8 is a flowchart illustrating a method for producing stretchable conductive nanofibers, according to example embodiments.

With reference to FIG. 8, a process for forming stretchable nanofibers (S310) is the same as S110 described previously for FIG. 4 so a repetitive description is omitted.

Next, carbon nanotubes are deposited on the stretchable nanofibers (S320). This process for depositing carbon nanotubes on the stretchable nanofibers may be performed as discussed previously in FIG. 4 (S120˜S140) so a repetitive description is omitted. Then, metal nanoparticles are deposited on the stretchable nanofibers having carbon nanotubes deposited thereon (S330). This process for depositing metal nanoparticles on the stretchable nanofibers including carbon nanotubes thereon may be performed as discussed previously in FIG. 6 (S220˜S240) so a repetitive description is omitted. FIG. 9 shows a process for forming stretchable conductive nanofibers by the deposition of carbon nanotubes and metal nanoparticles.

Further, metal nanoparticles may be first deposited and then carbon nanotubes may be deposited, unlike the order described above and illustrated in FIG. 9. Optionally, the deposition of carbon nanotubes and metal nanoparticles may be alternately and repeatedly performed. In this case, each process of carbon nanotubes and metal nanoparticles deposition may include deposition for several times. According to example embodiments, a solution used in a first dip coating process may be the same as or different than a solution used in a subsequent dip coating process.

The metal nanoparticles having a high conductivity and the carbon nanotubes having a high aspect ratio may form a composite percolation network, thereby enhancing the conductivity of stretchable conductive nanofibers and reducing the lowering of conductivity of stretchable conductive nanofibers during the stretching of the stretchable conductive nanofibers.

Furthermore, when forming a mat using stretchable nanofibers, a stretchable conductive mat may be formed by processes described above. The resulting stretchable conductive mat may be used as a stretchable electrode.

### EXAMPLE 1

10 parts by weight of SBS polymer are mixed with 100 parts by weight of a 3:1 mixed solution of tetrahydrofuran (THF) and acetone to prepare a SBS solution. The SBS solution is electrospinned to produce SBS nanofibers.

0.1 parts by weight of SWCNT are mixed with 100 parts by weight of a 4:1 mixed solution of water and isopropanol (IPA) to prepare a solution of carbon nanotubes. Using the solution of carbon nanotubes, a process for depositing carbon nanotubes on electrospinned SBS nanofibers is performed. In detail, electrospinned SBS nanofibers are immersed in the solution of carbon nanotubes for 2 minutes, and then they are removed from the solution and dried at room temperature.

### EXAMPLE 2

Carbon nanotubes are deposited on SBS nanofibers using the same process as in Example 1: immersing the SBS nanofibers in the solution of carbon nanotubes for 2 minutes, and then removing them from the solution and drying at room temperature. Then, the deposition process is repeated two times, thereby producing the SBS nanofibers having carbon nanotubes deposited thereon. Additionally, the SBS nanofibers are treated with UV-ozone between the first deposition and the second deposition and between the second deposition and the third deposition.

### EXAMPLE 3

SBS nanofibers having carbon nanotubes deposited thereon are produced using the same process as in Example 1, except for repeating the deposition of carbon nanotubes five times.

### EXAMPLE 4

SBS nanofibers having carbon nanotubes deposited thereon are produced using the same process as in Example 1, except for repeating the deposition of carbon nanotubes ten times.

### COMPARATIVE EXAMPLE

Electrospinned SBS nanofibers are produced using the same process as in Example 1.

### EXAMPLE 5

A mat is formed using SBS nanofibers having carbon nanotubes deposited thereon produced by the same process as in Example 4.

Tensile Test of SBS Nanofibers

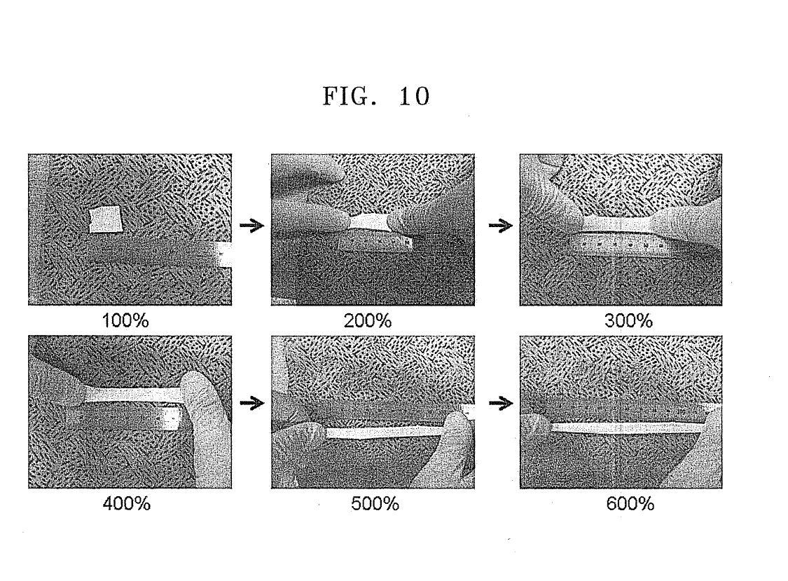

FIG. 10 includes photographs showing the extent of stretching the SBS nanofiber mat formed by electro-spinning in the intermediate stage of Example 5. In FIG. 10, it can be seen that the SBS nanofiber mat may be stretched 600% without breaking, wherein 100% represents that a length the SBS nanofiber mat when the mat is not stretched.

When a mat formed by bringing together fibers is stretched uniaxially, a stretch resistance is absent in directions other than the stretching direction, resulting in enhancing the stretchability of a nanofiber mat as compared to a film. Therefore, when an electrode or substrate is formed using stretchable conductive nanofibers, the stretchability of the resulting electrode or substrate may be better than stretchable thin film electrodes or stretchable substrates in the related art.

Electrical Conductivity According to the Number of Depositions

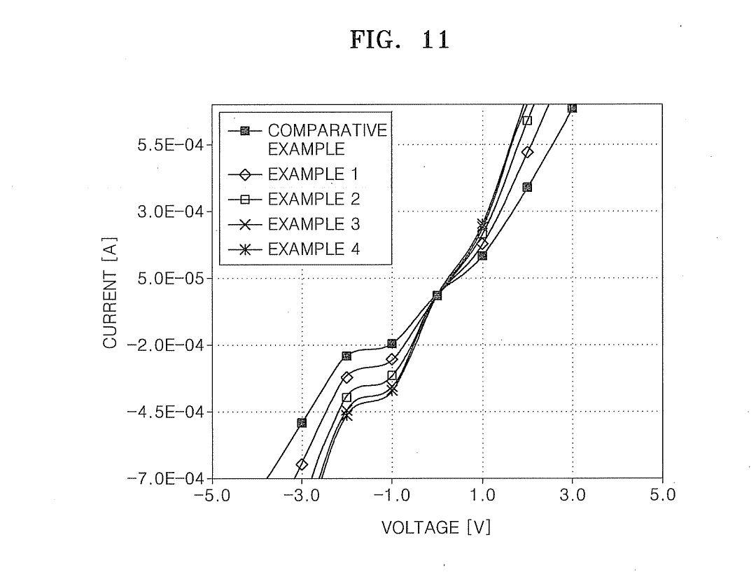

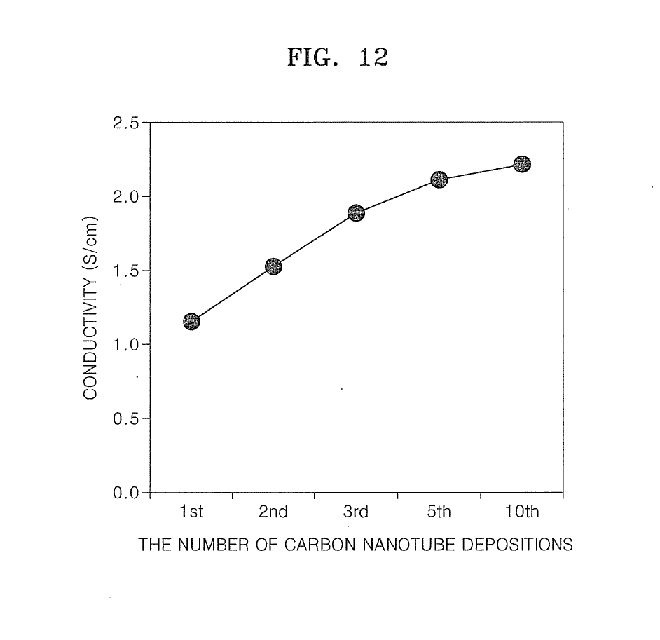

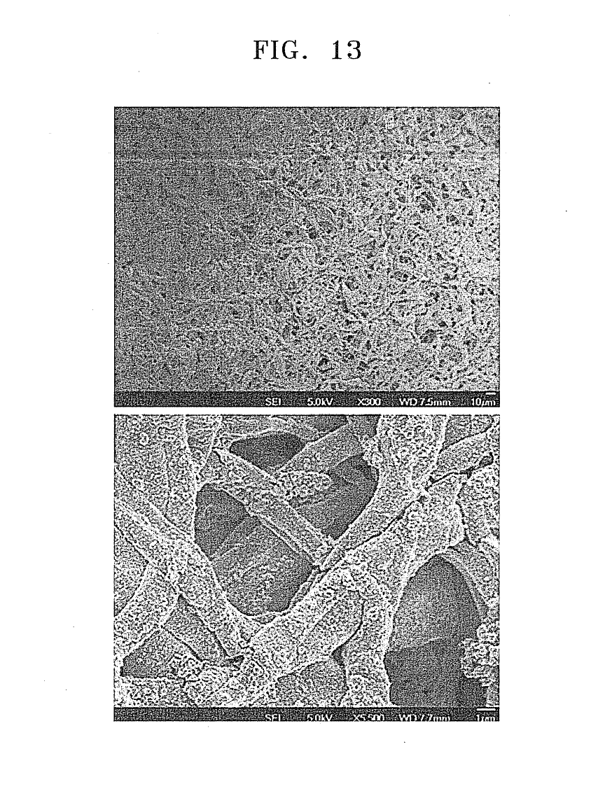

FIGS. 11 and 12 are graphs showing current-voltage properties and conductivities of carbon nanotubes-deposited SBS nanofibers according to the number of carbon nanotube depositions, respectively. The current-voltage properties and conductivities are measured on nanofibers. With reference to FIGS. 11 and 12, Example 4 in which carbon nanotube depositions are performed ten times has the highest conductivity, and Comparative Example in which only SBS nanofibers are formed has the lowest conductivity. As shown in FIG. 12, the conductivity of the carbon nanotubes-deposited SBS nanofibers increases as the number of carbon nanotube depositions is increased. This is because a percolation network may be more densely formed as the number of carbon nanotube depositions is increased. Further, as the number of carbon nanotube depositions is increased, the increase in conductivity saturates, which may be because the conductivity of carbon nanotubes-deposited nanofibers is nearly identical with the conductivity of carbon nanotubes.

Electrical Conductivity According to Stretching

Conductivities were measured while stretching uniaxially the carbon nanotubes-deposited SBS nanofiber mat formed in Example 5, the results of which are shown in Table 1. 100% represents that the mat is not stretched, and 200%, 300% and 400% represent that the mat is stretched by 2, 3 and 4 times its original length, respectively.

TABLE 1

| Stretching | Electrical conductivity (S/cm) |
|---|---|
| 100% | 2.21 |
| 200% | 2.01 |
| 300% | 0 |
| 400% | 0 |

From Table 1, the conductivity of the mat stretched by 200% is maintained at approximately the same value as the value prior to stretching, but with a slight reduction, which may be because a percolation network between carbon nanotubes after stretching is not significantly damaged due to the high aspect ratio of carbon nanotubes, thereby maintaining electrical conductive paths.

To the contrary, the conductivity of the mat stretched by 300% is dramatically reduced to 0, which may be because a percolation network between carbon nanotubes after stretching is broken.

### EXAMPLE 6

10 parts by weight of SBS polymer are mixed with 100 parts by weight of a 3:1 mixed solution of tetrahydrofuran (THF) and acetone to prepare a SBS solution. The SBS solution is electrospinned to produce a mat formed of SBS nanofibers.

Silver nitrate (AgNO₃) is dissolved in ethanol to prepare a 3 wt % solution of silver nitrate in ethanol. Silver nitrate is deposited on the mat of electrospinned SBS nanofibers using the silver nitrate solution to produce a SBS nanofiber mat having silver nitrate deposited thereon. The electrospinned SBS nanofiber mat is immersed in the silver nitrate solution for 5 minutes, and then it is removed from the solution and dried at room temperature. Then, the silver nitrate-deposited SBS nanofiber mat is treated with hydrazine (N₂H₄) vapor to reduce silver nitrate. The process of depositing and reducing silver nitrate on the SBS nanofiber mat is repeated five times to form the SBS nanofiber mat having silver nanoparticles deposited thereon.

FIG. 13 is a SEM photograph of the silver nanoparticles-deposited SBS nanofiber mat formed in Example 6. In FIG. 13, it can be seen that silver nanofibers are uniformly deposited (or substantially uniformly deposited) on SBS nanofibers.

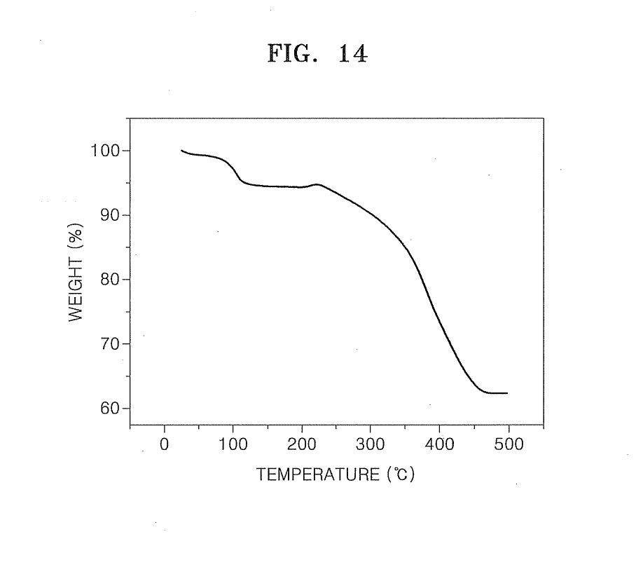

FIG. 14 is a thermogravimetry analysis graph showing a weight % of the silver nanoparticles-deposited SBS nanofiber mat formed in Example 6 with respect to temperature. The weight % of the silver nanoparticles-deposited SBS nanofiber mat represents the ratio of the weight of the silver nanoparticles-deposited SBS nanofiber mat (at a test temperature) to the weight of the silver nanoparticles-deposited SBS nanofiber mat (before heating the mat for the thermogravimetry analysis).

With reference to FIG. 14, the weight % of the silver nanoparticles-deposited SBS nanofiber mat is reduced by the evaporation of water at 100-200° C., and the weight is reduced by the sintering and burning of SBS nanofibers at 200-450° C. The constant weight at 450-500° C. is considered as the weight of silver residual (the melting point of 962° C.) after burning. This weight accounts for 62% of the weight of the silver nanoparticles-deposited SBS nanofiber mat at room temperature, and is over half the total mat weight.

It is believed that these results are owing to the fact that the silver nanoparticles-deposited SBS nanofiber mat formed in Example 6 contains silver at a high weight ratio to achieve a high conductivity, and enhance a percolation network of silver nanoparticles, thereby reducing significantly the lowering of conductivity of nanofibers during the stretching of nanofibers.

Electrical Conductivity According to Stretching

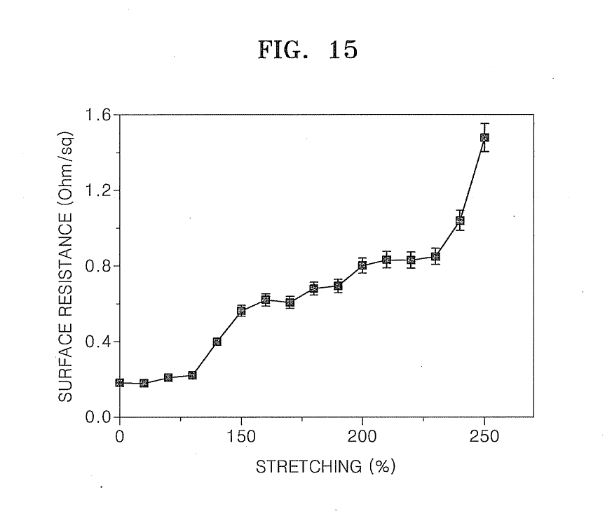

FIG. 15 is a graph showing surface resistance measurements while stretching uniaxially the silver nanoparticles-deposited SBS nanofiber mat formed in Example 6. With respect to FIG. 15, the surface resistance is gradually increased until 230% stretching, and then the surface resistance is dramatically increased for a stretching above 230%. Conductivities measuring while stretching uniaxially the silver nanoparticles-deposited SBS nanofiber mat formed in Example 6 are shown in Table 2.

TABLE 2

| Stretching | Electrical conductivity (S/cm) |
|---|---|
| 100% | 5.31 |
| 200% | 1.52 |
| 300% | 0 |

As can be seen from Table 2, although the conductivity at 200% stretching is dramatically lowered as compared to 100%, a significant conductivity value is maintained. Also, when the conductivities shown in Table 2 are compared to conductivities shown in Table 1, the conductivity prior to stretching is much greater in the silver nanoparticles-deposited SBS nanofiber mat of Example 6 than in the carbon nanotubes-deposited SBS nanofiber mat of Example 5. However, the conductivity after stretching is greater in the carbon nanotubes-deposited SBS nanofiber mat of Example 5 than in the silver nanoparticles -deposited SBS nanofiber mat of Example 6.

### EXAMPLE 7

A SBS nanofiber mat is produced from the SBS solution using the same process as in Example 5. Then, the carbon nanotubes-deposited SBS nanofiber mat is formed by depositing carbon nanotubes on the electrospinned SBS nanofiber mat using the same process as in Example 5. Silver nanoparticles are deposited on the carbon nanotubes-deposited SBS nanofiber mat using the same process as in Example 6. Each process of depositing carbon nanotubes and silver nanoparticles on SBS nanofibers is repeated five times to produce the carbon nanotubes and silver nanoparticles-deposited SBS nanofiber mat.

Electrical Conductivity According to Stretching

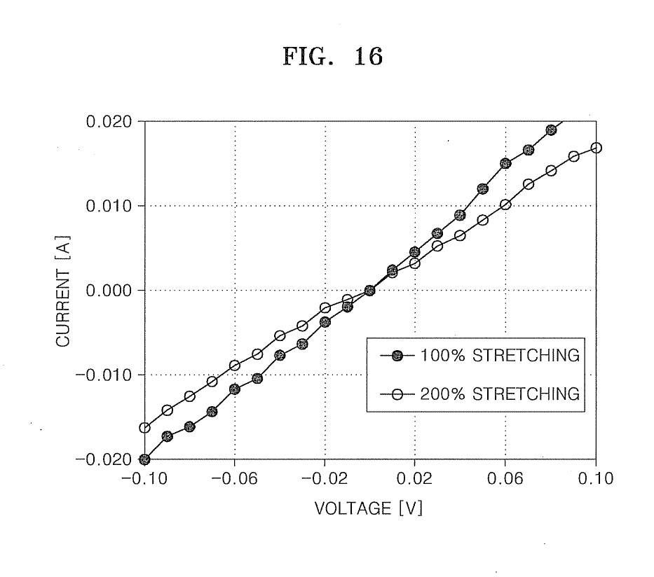

FIG. 16 is a graph showing current-to-voltage measurements while stretching uniaxially the carbon nanotubes and silver nanoparticles-deposited SBS nanofiber mat formed in Example 7. As can be seen from FIG. 14, when the same voltage is applied, the current is slightly reduced at 200% stretching as compared to 100%, but the degree of reduction is not big.

Conductivities are measured while stretching uniaxially the SBS nanofiber mat formed in Example 7, the results of which are shown in Table 3.

TABLE 3

| Stretching | Electrical conductivity (S/cm) |
|---|---|
| 100% | 5.52 |
| 200% | 4.30 |
| 300% | 0.52 |
| 400% | 0 |

As can be seen from Table 3, in the case of the carbon nanotubes and silver nanoparticles-deposited SBS nanofiber mat, the conductivity at 100% is higher than that of the silver nanoparticles-deposited SBS nanofiber mat, and the conductivity at 200% is higher than that of the carbon nanotubes-deposited SBS nanofiber mat. Also, the carbon nanotubes and silver nanoparticles-deposited SBS nanofiber mat exhibits conductivity to some degree at 300% stretching.

These results are because a composite percolation network of carbon nanotubes and silver nanoparticles is formed, thereby improving the conductivity of the carbon nanotubes prior to stretching as well as the conductivity of the carbon nanotubes after stretching by the guarantee of electrical paths.

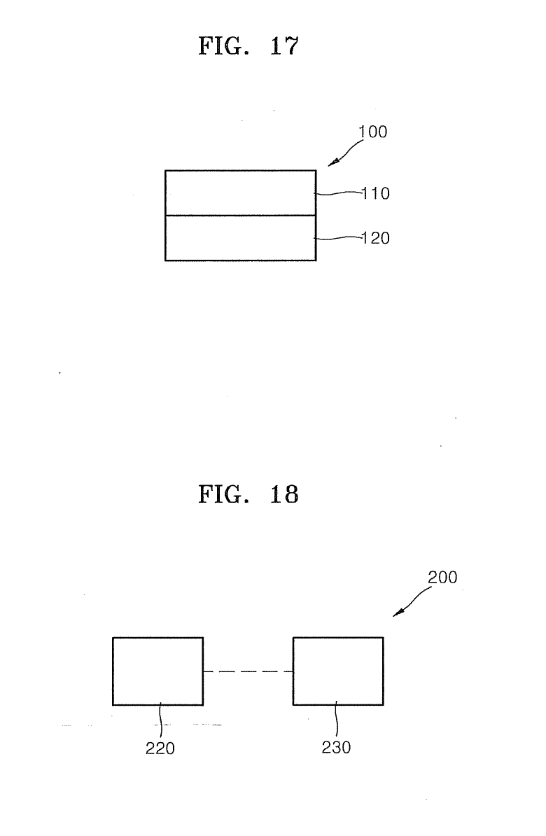

FIG. 17 is a view showing an electronic device according to example embodiments.

Referring to FIG. 17, an electronic device 100 (for example a solar cell, stretchable transistor, light-emitting device, but example embodiments are not limited thereto) includes at least one semiconductor layer 110 connected to at least one electrode 120. The electrode 120 may include stretchable conductive nanofibers 10, 20, and/or 30 according to example embodiments.

FIG. 18 is a view showing a sensor according to example embodiments.

Referring to FIG. 18, a sensor 200 (for example a gas sensor, light sensor, energy sensor, but example embodiments are not limited thereto) includes at least one electrode 220 configured to output a signal to a processor 230. The processor 230 may include a microprocessor, but example embodiments are not limited thereto. The electrode 220 may include stretchable conductive nanofibers 10, 20, and/or 30 according to example embodiments.

It should be understood that the example embodiments described herein should be considered in a descriptive sense only and not for purposes of limitation. Descriptions of features or aspects within some example embodiments should typically be considered as available for other similar features or aspects in other example embodiments.

While some example embodiments have been particularly shown and described, it will be understood by one of ordinary skill in the art that variations in form and detail may be made therein without departing from the spirit and scope of the claims.

What is claimed is:

1. A stretchable conductive nanofiber comprising:
at least one stretchable nanofiber; and
a conductive layer comprising carbon nanotubes and metal nanoparticles on a surface of the stretchable nanofiber.

2. The stretchable conductive nanofiber of claim 1, wherein the carbon nanotubes and the metal nanoparticles form a percolation network.

3. The stretchable conductive nanofiber of claim 1, wherein the stretchable nanofiber comprises stretchable polymers.

4. The stretchable conductive nanofiber of claim 3, wherein the stretchable polymers comprise one of polybutadiene (PB), poly(styrene-butadiene) (PS-b-PB, PS-co-PB), poly(styrene-butadiene-styrene) (PS-b-PB-b-PS) (SBS), poly(styrene-ethylene-butylene-styrene) (SEBS), polyurethane (PU), polyisoprene, and combinations thereof.

5. The stretchable conductive nanofiber of claim 1, wherein the carbon nanotubes include at least one of single-wall carbon nanotubes (SWNTs) and multi-wall carbon nanotubes (MWNTs).

6. The stretchable conductive nanofiber of claim 1, wherein the carbon nanotubes have an aspect ratio of 100˜5000.

7. The stretchable conductive nanofiber of claim 1, wherein the metal nanoparticles comprise at least one of silver, gold, copper, platinum, and combinations thereof.

8. The stretchable conductive nanofiber of claim 1, wherein the stretchable nanofiber comprises at least one of carbon nanotubes and metal nanoparticles inside the stretchable nanofiber.

9. A stretchable conductive nanofiber mat comprising at least one stretchable conductive nanofiber according claim 1.

10. A method for producing stretchable conductive nanofibers comprising:
(a) depositing carbon nanotubes on stretchable nanofibers by
immersing stretchable nanofibers in a solution of carbon nanotubes,
removing the stretchable nanofibers from the solution, and
drying the stretchable nanofibers;
(b) subjecting the stretchable nanofibers including carbon nanotubes deposited thereon to a UV-ozone treatment;
(c) additionally depositing carbon nanotubes on the stretchable nanofibers including carbon nanotubes deposited thereon by
immersing the stretchable nanofibers including carbon nanotubes deposited thereon in the solution of carbon nanotubes,
removing the stretchable nanofibers including carbon nanotubes deposited thereon, and
drying the stretchable nanofibers including carbon nanotubes deposited thereon; and
(d) repeating several times operations (b) and (c) sequentially to form a conductive layer comprising carbon nanotubes on the stretchable nanofibers.

11. The method according to claim 10, wherein the stretchable nanofibers comprise stretchable polymers.

12. The method according to claim 10, wherein the stretchable nanofibers are in the form of a mat.

13. A method for producing stretchable conductive nanofibers comprising:
(a) depositing metal precursors on stretchable nanofibers by
immersing stretchable nanofibers in a solution of metal precursors,
removing the stretchable nanofibers from the solution, and
drying the stretchable nanofibers;
(b) reducing the metal precursors deposited on the stretchable nanofibers to metals using a reducing agent; and
(c) repeating several times operations (a) and (b) to form a conductive layer comprising metal nanoparticles on the stretchable nanofibers.

14. The method according to claim 13, wherein the stretchable nanofibers comprise stretchable polymers.

15. The method according to claim 13, wherein the stretchable nanofibers are in the form of a mat.

16. The method according to claim 13, wherein the metal precursors include one of AgNO₃, AgCF₃COOH, HAuCl₄, CuCl₂, PtCl₂, PtCl₄. and a combination thereof.

17. The method according to claim 13, wherein the reducing agent includes one of hydrazine (N2H4) and Sodium borohydride (NaBH4).

18. A method for producing stretchable conductive nanofibers comprising:
(a) depositing carbon nanotubes on stretchable nanofibers by
immersing stretchable nanofibers in a solution of carbon nanotubes,
removing the stretchable nanofibers from the solution of carbon nanotubes, and
drying the stretchable nanofibers;
(b) depositing metal precursors on the stretchable nanofibers including carbon nanotubes deposited thereon by
immersing the stretchable nanofibers including carbon nanotubes deposited thereon in a solution of metal precursors,
removing the stretchable nanofibers including carbon nanotubes deposited thereon from the solution of metal precursors,
drying the stretchable nanofibers including carbon nanotubes deposited thereon, and
reducing the metal precursors to metals using a reducing agent; and
(c) repeating several times operations (a) and (b) to form a conductive layer comprising carbon nanotubes and metal nanoparticles on the stretchable nanofibers.

19. The method according to claim 18, wherein the stretchable nanofibers comprise stretchable polymers.

20. The method of claim 18, wherein the stretchable polymers comprise one of polybutadiene, poly(styrene-butadiene), poly(styrene-butadiene-styrene), poly(styrene-ethylene-butylene-styrene), polyurethane, polyisoprene, and combinations thereof.

21. The method according to claim 18, wherein the stretchable nanofibers are in the form of a mat.

22. The method according to any one of claims 18, wherein the metal precursors comprise one of AgNO₃, AgCF₃COOH, HAuCl₄, CuCl₂, PtCl₂, PtCl₄, and combinations thereof.

23. The method according to claim 18, wherein the reducing agent includes one of hydrazine (N₂H₄) and Sodium borohydride (NaBH₄).
